(19) United States
(12) Patent Application Publication
(10) Pub. No.: US 2025/0341770 A1
(43) Pub. Date: Nov. 6, 2025

(54) PATTERN FOR OPTICAL PROXIMITY CORRECTION AND DESIGNING METHOD OF PHOTOMASK PATTERN

(71) Applicant: Powerchip Semiconductor Manufacturing Corporation, Hsinchu (TW)

(72) Inventors: Kuei Yu Chien, Miaoli County (TW); Yung Ching Mai, Taipei City (TW); Shin-Shing Yeh, Changhua County (TW)

(73) Assignee: Powerchip Semiconductor Manufacturing Corporation, Hsinchu (TW)

(21) Appl. No.: 18/820,301

(22) Filed: Aug. 30, 2024

(30) Foreign Application Priority Data
May 6, 2024 (TW) 113116682

(51) Int. Cl. G03F 1/36; G03F 7/00

(52) U.S. Cl. CPC G03F 1/36; G03F 7/70441

(57) ABSTRACT

Provided are a pattern for optical proximity correction and a designing method of a photomask pattern. The pattern for optical proximity correction includes a main body portion and a T-shaped portion. The main body portion has at least one right-angled corner. The right-angled corner is composed of a first side and a second side. The T-shaped portion includes a head portion and an extension portion. The extension portion is connected to the right-angled corner. An angle between an extension direction of the extension portion and the first side or the second side is between 130 degrees and 140 degrees.

### CROSS-REFERENCE TO RELATED APPLICATION

This application claims the priority benefit of Taiwan application serial no. 113116682, filed on May 6, 2024. The entirety of the above-mentioned patent application is hereby incorporated by reference herein and made a part of this specification.

### BACKGROUND

### Technical Field

The disclosure relates to a pattern for optical proximity correction (OPC) and a designing method of a photomask pattern.

### Description of Related Art

In the semiconductor manufacturing process, in order to form specific component patterns (such as gates, pads, etc.) on the substrate, the corresponding patterns are first designed in the computer system, and then OPC is performed to generate a correction pattern. Then, the correction pattern is transferred to a photomask to form a photomask pattern. Afterwards, the photomask pattern is transferred to a material layer using a photolithography step and an etching step.

However, for patterns with right-angled corners, the current OPC technology still cannot effectively solve the problem of corner rounding, making it impossible to accurately form the desired pattern in the material layer.

### SUMMARY

The disclosure provides a pattern for optical proximity correction, which includes a T-shaped portion connected to a right-angled corner of a main body portion.

The disclosure provides a designing method of a photomask pattern, in which a first pattern to be transferred into a material layer is corrected before optical proximity correction is performed.

A pattern for optical proximity correction of the disclosure includes a main body portion and a T-shaped portion. The main body portion has at least one right-angled corner. The right-angled corner is composed of a first side and a second side. The T-shaped portion includes a head portion and an extension portion. The extension portion is connected to the right-angled corner. An angle between an extension direction of the extension portion and the first side or the second side is between 130 degrees and 140 degrees.

In an embodiment of the pattern for optical proximity correction of the disclosure, the extension portion extends toward an outside of the main body portion.

In an embodiment of the pattern for optical proximity correction of the disclosure, the T-shaped portion is a T-shaped recess, and the extension portion extends toward an inside of the main body portion.

In an embodiment of the pattern for optical proximity correction of the disclosure, a distance between a junction of a side wall of the extension portion and the first side and a vertex of the right-angled corner is no more than ⅓ of a length of the first side.

In an embodiment of the pattern for optical proximity correction of the disclosure, a distance between a junction of a side wall of the extension portion and the second side and the vertex of the right-angled corner is no more than ⅓ of a length of the second side.

A designing method of a photomask pattern of the disclosure includes the following steps. A first pattern to be transferred into a material layer is provided. The first pattern includes a main body portion having at least one right-angled corner, and the right-angled corner is composed of a first side and a second side. The first pattern is corrected to form a second pattern. The second pattern includes the main body portion and a T-shaped portion. The T-shaped portion includes a head portion and an extension portion. The extension portion is connected to the right-angled corner, and an angle between an extension direction of the extension portion and the first side or the second side is between 130 degrees and 140 degrees. Optical proximity correction is performed on the second pattern to form a photomask pattern.

In an embodiment of the designing method of the photomask pattern of the disclosure, the extension portion extends toward an outside of the main body portion.

In an embodiment of the designing method of the photomask pattern of the disclosure, the T-shaped portion is a T-shaped recess, and the extension portion extends toward an inside of the main body portion.

In an embodiment of the designing method of the photomask pattern of the disclosure, a distance between a junction of a side wall of the extension portion and the first side and a vertex of the right-angled corner is no more than ⅓ of a length of the first side.

In an embodiment of the designing method of the photomask pattern of the disclosure, a distance between a junction of a side wall of the extension portion and the second side and the vertex of the right-angled corner is no more than ⅓ of a length of the second side.

Based on the above, in the designing method of the photomask pattern of the disclosure, before optical proximity correction is performed, the first pattern to be transferred into the material layer is corrected to form the second pattern including the main body portion and the T-shaped portion. In the second pattern, the T-shaped portion is connected to the right-angled corner of the main body portion. Therefore, when the second pattern is subsequently subjected to optical proximity correction, the T-shaped portion can be further corrected. That is, a more subtle correction can be made to the right-angled corner of the main body portion to solve the problem of corner rounding.

### BRIEF DESCRIPTION OF THE DRAWINGS

FIG. 1 is a flowchart of a designing method of a photomask pattern according to an embodiment of the disclosure.

FIG. 2 is a schematic diagram of a first pattern according to a first embodiment of the disclosure.

FIG. 3 is a schematic diagram of a second pattern according to the first embodiment of the disclosure.

FIG. 4 is a schematic diagram of a correction pattern according to the first embodiment of the disclosure.

FIG. 5 is a schematic diagram of a first pattern according to a second embodiment of the disclosure.

FIG. 6 is a schematic diagram of a second pattern according to the second embodiment of the disclosure.

FIG. 7 is a schematic diagram of a correction pattern according to the second embodiment of the disclosure.

### DESCRIPTION OF THE EMBODIMENTS

Hereinafter, exemplary embodiments will be described in detail with reference to the accompanying drawings, but the provided embodiments are not intended to limit the scope of the disclosure. In addition, the drawings are for illustrative purposes only and may not be drawn to scale. In order to facilitate understanding of the disclosure, the same elements will be denoted by the same reference numerals in the following description.

Terms such as “containing,” “including,” “having,” etc. used in this specification are all open-ended terms, that is, meaning “including but not limited to.”.

When terms such as “first,” “second,” etc. are used to describe the elements, they are only used to distinguish these elements from each other and are not intended to limit the order or importance of the elements. Therefore, in some cases, the first element may also be referred to as the second element, and the second element may also be referred to as the first element, without departing from the scope of the disclosure.

In the embodiment, a designing method of a photomask pattern is used to form the photomask pattern, and after using a photomask having the photomask pattern to perform a photolithography step and an etching step, a desired pattern can be precisely formed in a material layer. This is explained in detail below.

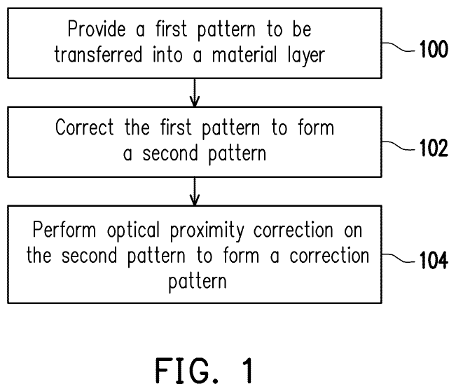

FIG. 1 is a flowchart of a designing method of a photomask pattern according to an embodiment of the disclosure.

Referring to FIG. 1, first, in step 100, a first pattern to be transferred into the material layer is provided. In the embodiment, the first pattern corresponds to a target pattern to be formed in the material layer. When the photomask is used for the photolithography step and the etching step, there will be a difference between the pattern formed in the material layer and the target pattern due to the optical proximity effect in the photolithography process or the loading effect in the etching step. Therefore, in the embodiment, the first pattern is corrected, and the corrected first pattern is used to form the photomask pattern, so that the pattern formed in the material layer accurately corresponds to the target pattern. For example, the first pattern corresponding to the target pattern to be formed in the material layer may be input into the computer system for correction.

In the embodiment, as shown in FIG. 2, a first pattern 20 includes a rectangular main body portion 200. The main body portion 200 has four right-angled corners CR. Each right-angled corner CR is composed of two sides, and the right-angled corner CR has a vertex V. Taking the right-angled corner CR located at the upper left corner in FIG. 2 as an example, it is composed of a first side S1 and a second side S2.

Then, in step 102, the first pattern 20 is corrected to form a second pattern 30. In the embodiment, the right-angled corners CR of the first pattern 20 can be corrected in the computer system.

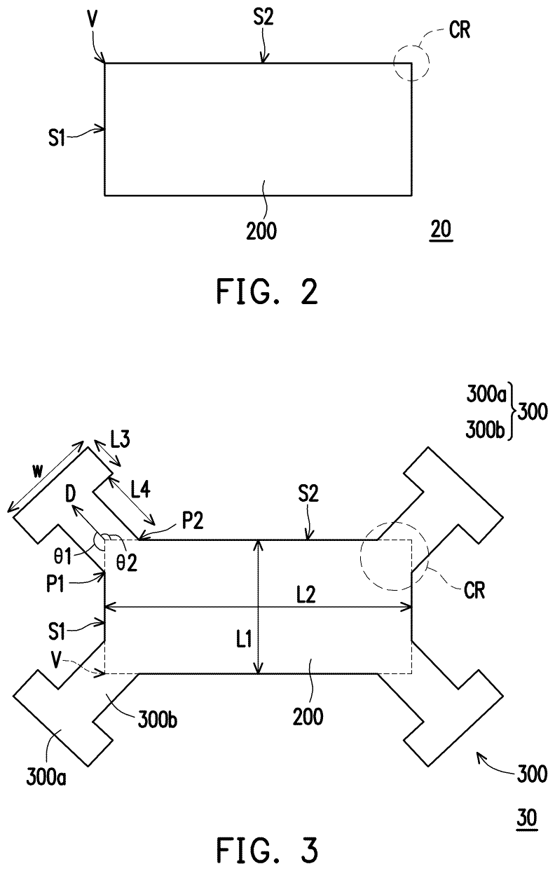

In the embodiment, as shown in FIG. 3, after the first pattern 20 is corrected, the second pattern 30 formed includes the main body portion 200 and four T-shaped portions 300. Each of the four T-shaped portions 300 is connected to one right-angled corner CR of the main body portion 200. The T-shaped portion 300 includes a head portion 300a and an extension portion 300b, and the extension portion 300b is connected to the right-angled corner CR. That is to say, the T-shaped portion 300 is connected to the right-angled corner CR of the main body portion 200 with the head portion 300a facing outward. In addition, an angle between an extension direction D of the extension portion 300b and the first side S1 or the second side S2 is between 130 degrees and 140 degrees. In the embodiment, an angle θ1 between the extension direction D of the extension portion 300b and the first side S1 and an angle θ2 between the extension direction D and the second side S2 are each 135 degrees. That is to say, in the embodiment, the T-shaped portion 300 can extend from the vertex V of the right-angled corner CR toward an outside of the main body portion 200 along an angle bisector.

In the embodiment, a distance between a junction of a side wall of the extension portion 300b and a side of the main body portion 200 and the vertex V of the right-angled corner CR is no more than ⅓ of a length of the side. For example, as shown in FIG. 3, a distance between a junction P1 of a side wall of the extension portion 300b adjacent to the first side S1 and the first side S1 and the vertex V of the right-angled corner CR is no more than ⅓ of a length L1 of the first side S1. Similarly, a distance between a junction P2 of a side wall of the extension portion 300b adjacent to the second side S2 and the second side S2 and the vertex V of the right-angled corner CR is no more than ⅓ of a length L2 of the second side S2. In addition, a width W and a length L3 of the head 300a and a length L4 of the side of the extension portion 300b must not be less than the minimum allowable length of subsequent optical proximity correction. That is to say, a size of each side of the T-shaped portion 300 must be no less than the minimum allowable length of subsequent optical proximity correction. Therefore, the T-shaped portion 300 can be used for subsequent optical proximity correction.

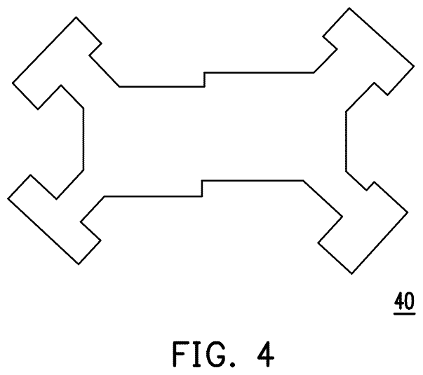

Afterwards, in step 104, optical proximity correction is performed on the second pattern 30 to form a correction pattern 40, as shown in FIG. 4. The correction pattern 40 is the photomask pattern subsequently formed on the photomask. In this way, the design of the photomask pattern of the embodiment is completed. In the embodiment, since the T-shaped portions 300 are connected to the right-angled corners CR of the main body portion 200, the T-shaped portions 300 can be further corrected when optical proximity correction is performed. That is, a more subtle correction can be made to the right-angled corners CR of the main body portion 200 to solve the problem of corner rounding.

After the design of the photomask pattern is completed, the correction pattern 40 can be transferred to the photomask through commonly known steps to form the photomask pattern. Then, the photomask pattern is transferred to the material layer using the photolithography step and the etching step to form the desired pattern in the material layer. In the embodiment, before optical proximity correction is performed, the first pattern 20 is corrected in advance, and the corrected pattern is then subjected to optical proximity correction to form the photomask pattern. Therefore, the pattern corresponding to the first pattern 20 can be accurately formed in the material layer.

In the embodiment, the first pattern 20 includes the rectangular main body portion 200, and the T-shaped portion 300 extends toward the outside of the main body portion 200, but the disclosure is not limited thereto. In other embodiments, the first pattern corresponding to the target pattern to be formed in the material layer may have other shapes, and the T-shaped portion may be a T-shaped recess extending toward an inside of the main body portion.

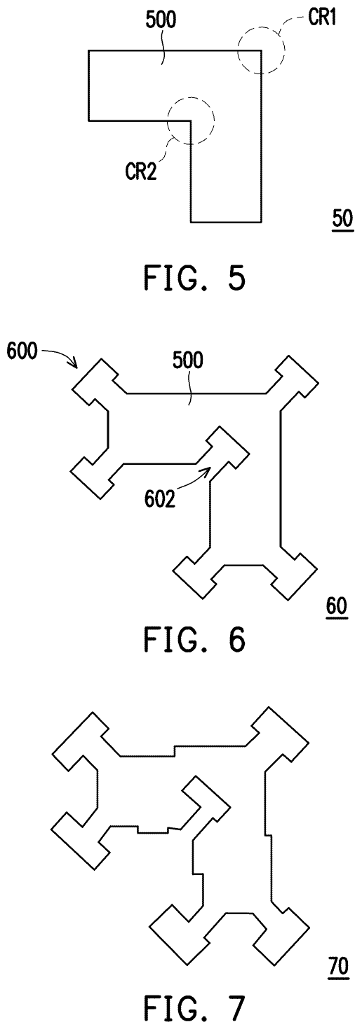

FIG. 5 is a schematic diagram of a first pattern according to a second embodiment of the disclosure. FIG. 6 is a schematic diagram of a second pattern according to the second embodiment of the disclosure. FIG. 7 is a schematic diagram of a correction pattern according to the second embodiment of the disclosure.

Referring to FIG. 5, FIG. 6, and FIG. 7 at the same time, in the embodiment, a first pattern 50 corresponding to the target pattern to be formed in the material layer includes an L-shaped main body portion 500. The main body portion 500 has five outer right-angled corners CR1 and one inner right-angled corner CR2. After correction is made to the outer right-angled corners CR1 and the inner right-angled corner CR2 of the first pattern 50, a second pattern 60 is formed. The second pattern 60 includes the main body portion 500, five T-shaped portions 600 located at CR1, and one T-shaped recess 602 located at CR2. The design rules of the T-shaped portions 600 and the T-shaped recess 602 are the same as the design rules of the T-shaped portions 300 in the first embodiment, and will not be repeated here.

In the embodiment, the T-shaped recess 602 extends toward an inside of the main body portion 500. In detail, the T-shaped recess 602 is connected to the inner right-angled corner CR2 of the main body portion 500 with the head facing inward. That is to say, in the embodiment, the T-shaped recess 602 extends from a vertex of the inner right-angled corner CR2 toward the inside of the main body portion 500 along an angle bisector.

After optical proximity correction is performed on the second pattern 60, a correction pattern 70 is formed as the photomask pattern formed on the photomask.

In the embodiment, since the T-shaped portions 600 are connected to the outer right-angled corners CR1 of the main body portion 500, and the T-shaped recess 602 is connected to the inner right-angled corner CR2 of the main body portion 500, further correction can be made to the T-shaped portions 600 and the T-shaped recess 602 when optical proximity correction is performed. That is, a more subtle correction can be made to the outer right-angled corners CR1 and the inner right-angled corner CR2 of the main body portion 500 to solve the problem of corner rounding.

Although the disclosure has been described with reference to the embodiments above, the embodiments are not intended to limit the disclosure. Any person skilled in the art can make some changes and modifications without departing from the spirit and scope of the disclosure. Therefore, the scope of the disclosure will be defined in the appended claims.

What is claimed is:

1. A pattern for optical proximity correction, comprising:
a main body portion, having at least one right-angled corner, wherein the right-angled corner is composed of a first side and a second side; and
a T-shaped portion, comprising a head portion and an extension portion, wherein the extension portion is connected to the right-angled corner,
wherein an angle between an extension direction of the extension portion and the first side or the second side is between 130 degrees and 140 degrees.

2. The pattern for optical proximity correction according to claim 1, wherein the extension portion extends toward an outside of the main body portion.

3. The pattern for optical proximity correction according to claim 1, wherein the T-shaped portion is a T-shaped recess, and the extension portion extends toward an inside of the main body portion.

4. The pattern for optical proximity correction according to claim 1, wherein a distance between a junction of a side wall of the extension portion and the first side and a vertex of the right-angled corner is no more than ⅓ of a length of the first side.

5. The pattern for optical proximity correction according to claim 1, wherein a distance between a junction of a side wall of the extension portion and the second side and a vertex of the right-angled corner is no more than ⅓ of a length of the second side.

6. A designing method of a photomask pattern, comprising:
providing a first pattern to be transferred into a material layer, wherein the first pattern comprises a main body portion, the main body portion has at least one right-angled corner, and the right-angled corner is composed of a first side and a second side;
correcting the first pattern to form a second pattern, wherein the second pattern comprises the main body portion and a T-shaped portion, the T-shaped portion comprises a head portion and an extension portion, the extension portion is connected to the right-angled corner, and an angle between an extension direction of the extension portion and the first side or the second side is between 130 degrees and 140 degrees; and
performing optical proximity correction on the second pattern to form the photomask pattern.

7. The designing method of the photomask pattern according to claim 6, wherein the extension portion extends toward an outside of the main body portion.

8. The designing method of the photomask pattern according to claim 6, wherein the T-shaped portion is a T-shaped recess, and the extension portion extends toward an inside of the main body portion.

9. The designing method of the photomask pattern according to claim 6, wherein a distance between a junction of a side wall of the extension portion and the first side and a vertex of the right-angled corner is no more than ⅓ of a length of the first side.

10. The designing method of the photomask pattern according to claim 6, wherein a distance between a junction of a side wall of the extension portion and the second side and a vertex of the right-angled corner is no more than ⅓ of a length of the second side.
